(19) United States
(12) Patent Application Publication
(10) Pub. No.: US 2009/0316372 A1
(43) Pub. Date: Dec. 24, 2009

(54) Printed circuit board assembly

(76) Inventor: Albert David Kozlovski, Atkinson, NH (US)

Correspondence Address: CHRISTOPHER P. MAIORANA, P.C., 24840 HARPER SUITE 100, ST. CLAIR SHORES, MI, 48080, US

(21) Appl. No.: 12/144,886

(22) Filed: Jun. 24, 2008

(51) Int. Cl. H05K 5/00

(52) U.S. Cl. 361/757

(57) ABSTRACT

A system, apparatus and method are described for a printed circuit board assembly. The printed circuit board assembly may include a printed circuit board, a base, and a housing that includes one or more elastomeric pads that may contact the printed circuit board when the printed circuit board assembly is assembled. Other embodiments are described and claimed.

### BACKGROUND

In a printed circuit board assembly, a printed circuit board is commonly attached to a base by screws. However, during the attachment, the screws transmit shock and vibration to the printed circuit board and its electrical components. There may be a need for a printed circuit board assembly that does not use screws that extend through the printed circuit board to attach the printed circuit board to a base.

### BRIEF DESCRIPTION OF THE DRAWINGS

FIG. 1 illustrates an exploded perspective view of a printed circuit board assembly, in accordance with one embodiment.

FIG. 2 illustrates an exploded interior side view of a printed circuit board assembly, in accordance with one embodiment.

FIG. 3 illustrates a bottom view of a base for a printed circuit board assembly, in accordance with one embodiment.

FIG. 4 illustrates a front view of a base for a printed circuit board assembly, in accordance with one embodiment.

FIG. 5 illustrates a cross section of the base of FIG. 3 taken along the line A-A, in accordance with one embodiment.

FIG. 6 illustrates a top view of a housing, not showing elastomeric pads, for a printed circuit board assembly, in accordance with one embodiment.

FIG. 7 illustrates a front view of a housing, not showing elastomeric pads, for a printed circuit board assembly, in accordance with one embodiment.

FIG. 8 illustrates a side view of a housing, not showing elastomeric pads, for a printed circuit board assembly, in accordance with one embodiment.

FIG. 9 illustrates a top view of a housing, including an overmold, for a printed circuit board assembly, in accordance with one embodiment.

FIG. 10 illustrates a cross section of the housing of FIG. 9 taken along the line B-B, in accordance with one embodiment.

FIG. 11 illustrates a perspective view of a printed circuit board assembly showing some internal components, in accordance with one embodiment.

FIG. 12 illustrates a cross section of the printed circuit board assembly of FIG. 11 taken along line C-C, in accordance with one embodiment.

FIG. 13 illustrates a cross section of components of the printed circuit board assembly of FIG. 11 taken along line D-D, but with the housing net yet assembled, in accordance with one embodiment.

FIG. 14 illustrates a cross section of components of the printed circuit board assembly of FIG. 11 taken along line E-E, but with the housing net yet assembled, in accordance with one embodiment.

FIG. 15 illustrates the cross section of FIG. 13, but with the housing snap-fitted to the base and around the printed circuit board, in accordance with one embodiment.

FIG. 16 illustrates a front view of FIG. 14, but with the housing snap-fitted to the base and around the printed circuit board, in accordance with one embodiment.

### DETAILED DESCRIPTION

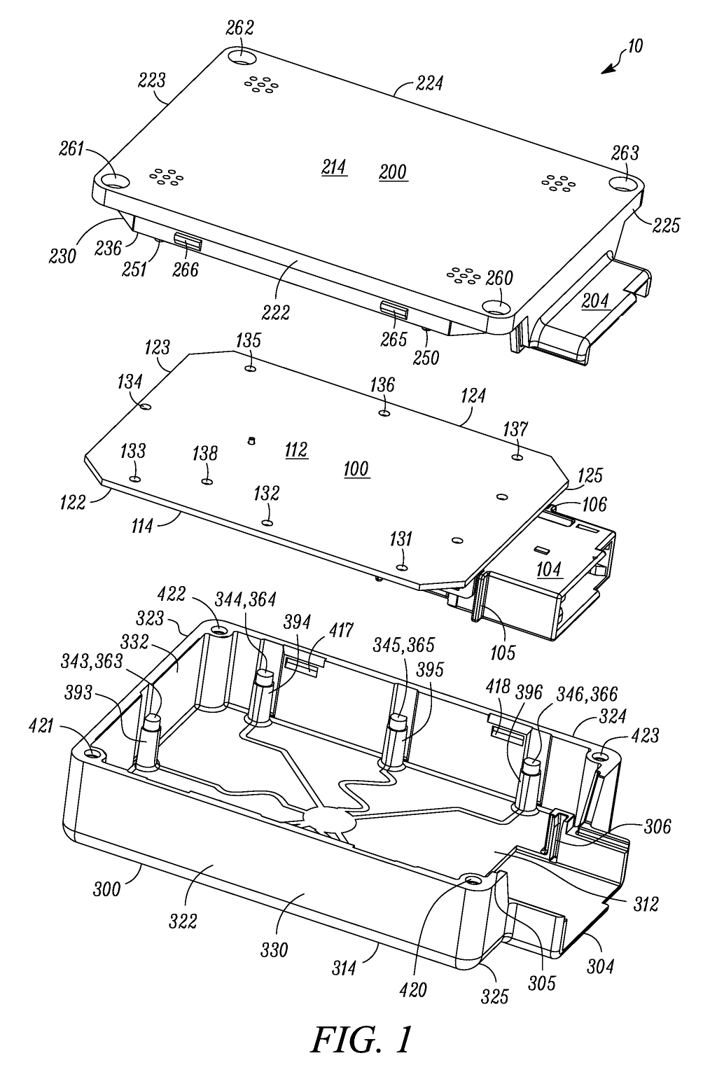

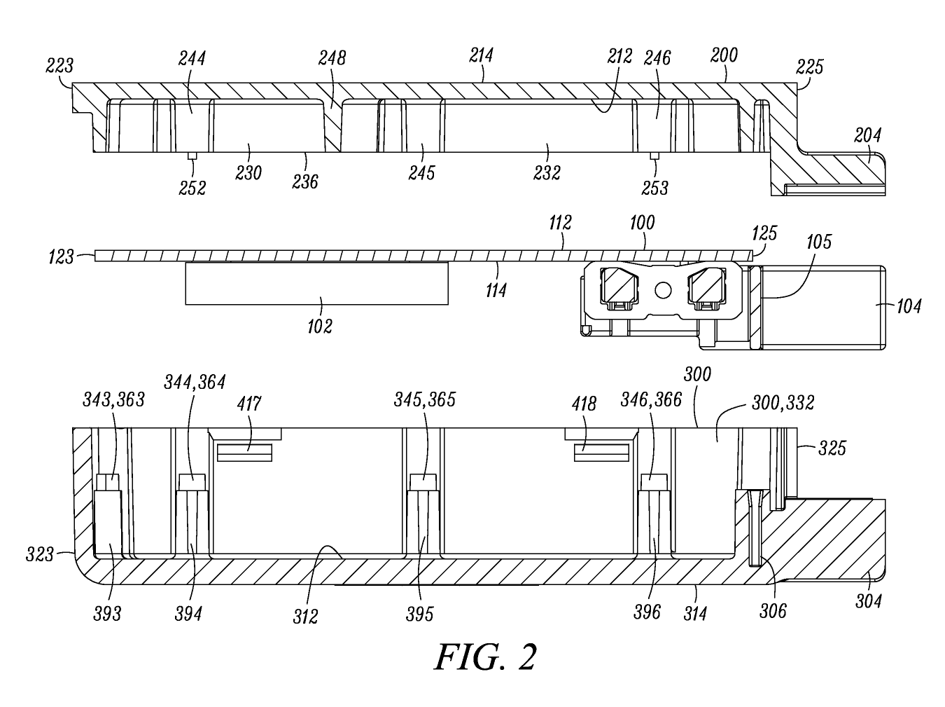

FIGS. 1-2 show an exploded perspective and exploded interior side view, respectively, of a printed circuit board assembly 10, in accordance with one embodiment. The printed circuit board assembly 10 may include a printed circuit board 100, a base 200, and a housing 300. Embodiments of elements shown in FIGS. 1-2 are discussed below with respect to other figures.

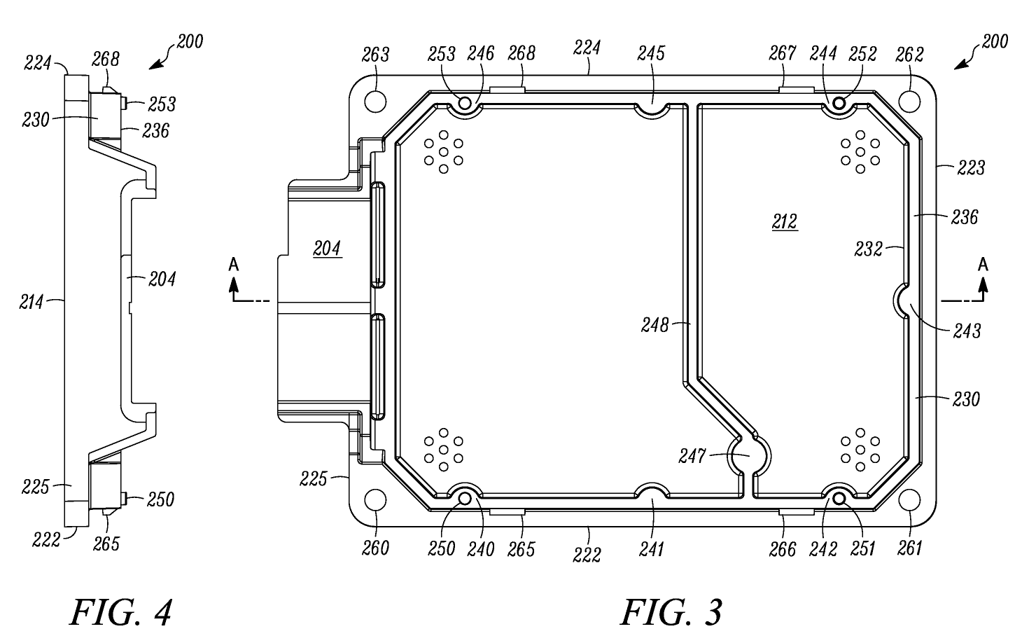

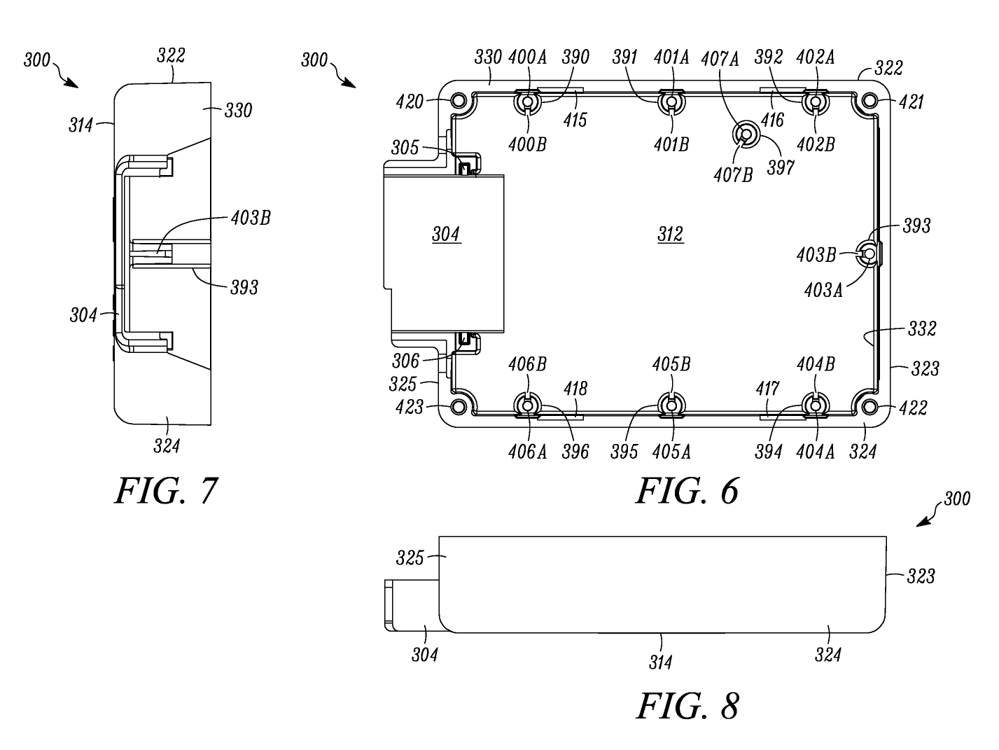

The printed circuit board 100 may include a first face 112 and second face 114, and first side 122, second side 123, third side 124, and fourth side 125. The printed circuit board may be shaped such that its first face 112 and second face 114 are rectangular but with chamfered corners, such as shown in FIG. 1, or may be another shape. When the printed circuit board assembly 10 is assembled, the first face 112 of the printed circuit board 100 may face the inner face 212 of the base 200, and the second face 114 may face the inner face 312 of the housing 300. Embodiments of the base 200 are described below with respect to FIGS. 3-5, for example. Embodiments of the housing 300 are described below with respect to FIGS. 6-10, for example.

An antenna 102 and a connector 104 may be secured to the printed circuit board 100. The antenna 102 may be secured by adhesive or other means. The connector 104 may include connector ears 105-106, which may respectively extend into the connector slots 305-306 of the housing 300 during assembly of the printed circuit board assembly 10. The connector ears 105-106, when extending into the connector slots 305-306, may support the connector 104 by providing a resisting force against the force caused by attaching a mating connector. The connector ears 105-106 may also position the connector 104 adjacent to the connector cover 304. The connector 104 may be soldered or otherwise secured to the printed circuit board 100. At least part of the connector 104 may be positioned adjacent to the second face 114, and may extend outward from the fourth side 125.

The printed circuit board 100 may include one or more positioning holes therein in various embodiments. For example, in one embodiment, such as shown in FIG. 1, the printed circuit board 100 includes seven positioning holes 131-137, each located near one of the sides 122-125 of the printed circuit board 100, and an eighth positioning hole 138 located further from any one of the sides 122-125. The positioning holes 131-138 may extend through the printed circuit board 100, from the first face 112 to the second face 114. The positioning holes 131-138 may each be variously located in the printed circuit board 100.

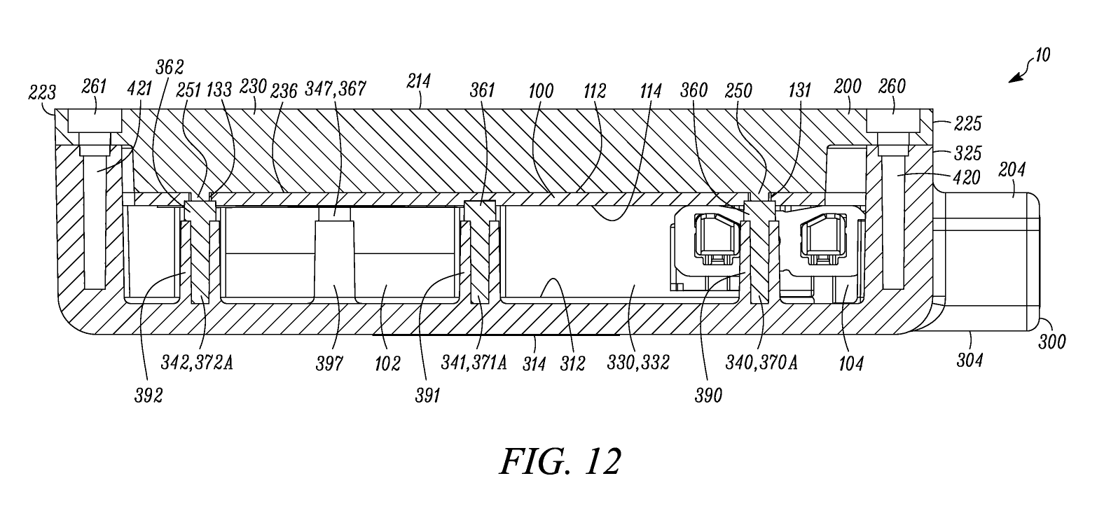

The positioning holes 131-138 may position the printed circuit board 100 with respect to the base 200 during assembly of the printed circuit board assembly 10. One or more of the positioning holes 131-138 of the printed circuit board 100 may be disposed on locator pins of the base 200 during assembly of the printed circuit board assembly 10 to position the printed circuit board 100 with respect to the base 200, such as described below with respect to FIG. 12 and otherwise. One or more elastomeric pads of the housing 300 may contact the printed circuit board 100, possibly adjacent to a different one of the positioning holes 131-138, as assembled. The elastomeric pads may press against the printed circuit board 100, possibly each extending into one of the positioning holes 131-138, to hold the printed circuit board 100 in place against it and the base 200, such as described below.

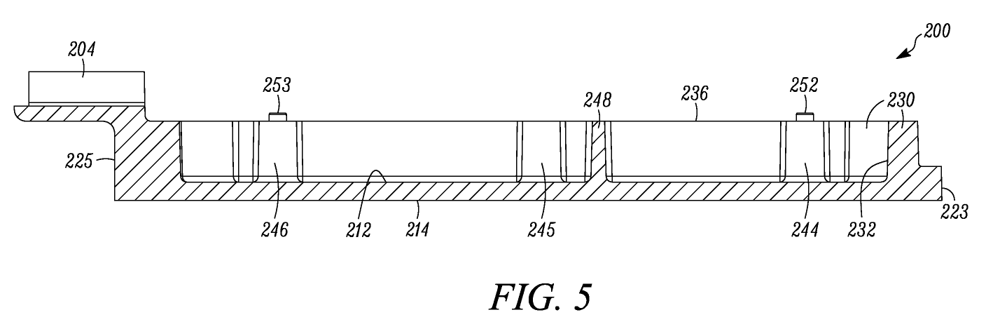

FIGS. 3-4 illustrate a bottom and front view, respectively, of a base 200 for a printed circuit board assembly 10, in accordance with one embodiment. FIG. 5 illustrates a cross section of the base 200 of FIG. 3 taken along the line A-A. Referring to FIGS. 1-5, the base 200 may include an inner face 212 and outer face 214, and first side 222, second side 223, third side 224, and fourth side 225. The base 200 may be made of a conductive plastic, for example, or another material or materials.

The base 200 may include a connector seat 204. The connector seat 204 may extend from the inner face 212 and fourth side 225 of the base 200. The connector seat 204 may be shaped and sized to be positioned adjacent to the connector 104 of the printed circuit board 100 when the printed circuit board assembly 10 is assembled.

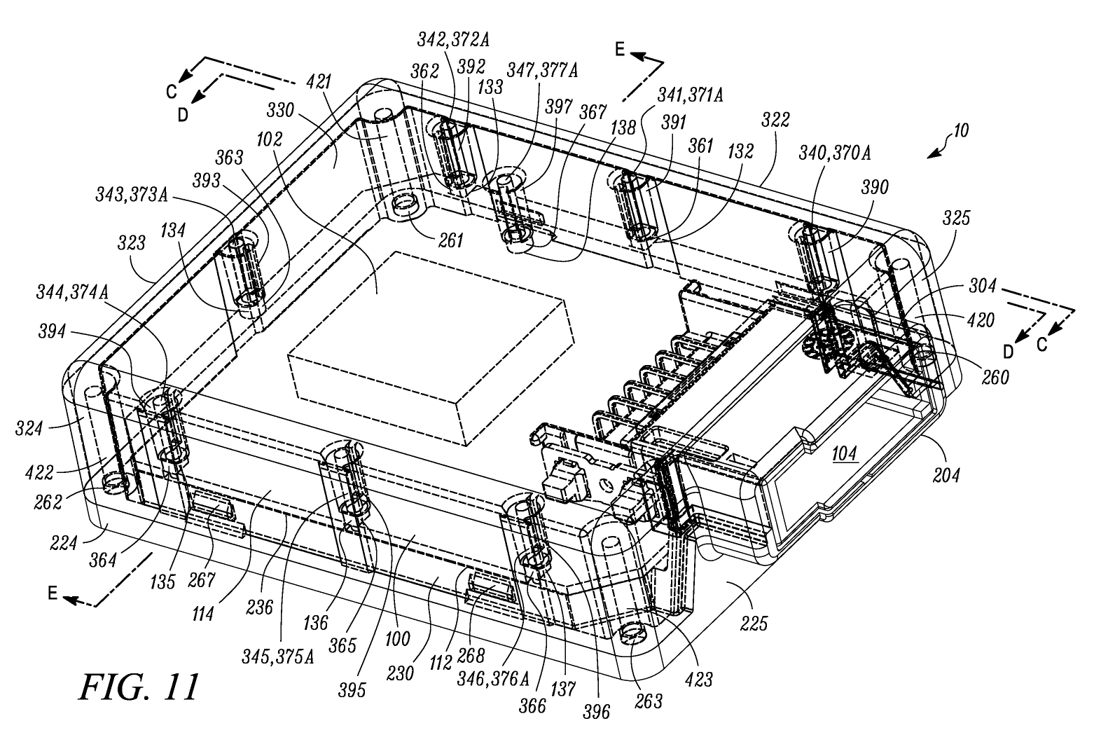

The base 200 may include a wall 230, which may extend from the inner face 212 of the base 200. The wall 230 may be perpendicular or close to perpendicular to the inner face 212, or may have another relative orientation. The wall 230 may include an inner surface 232, which may face toward the interior of the printed circuit board assembly 10 as assembled. The wall 230 may include a top face 236. The printed circuit board 100 may be positioned on the top face 236 of the wall 230 when assembled, such that the printed circuit board 100 near its periphery is disposed adjacent to the top face 236, such as shown in FIGS. 11-16, which are described below. The wall 230 and its top face 236 may be alternatively sized and shaped as desired.

In various embodiments, the wall 230 includes one or more projections that project from its inner surface 232. In one embodiment, the wall 230 includes seven projections 240-246. The projections 240-246 may each be shaped as a partial cylinder. The projections 240-246 may each have a length that extends from the inner face 212 of the base 200 to the top face 236 of the wall 230 of the base 200, such that the top of the projections 240-246 form part of the top face 236. The projections 240-246 may be otherwise shaped and sized as desired.

In an embodiment, the projections 240-246 may be positioned to be respectively disposed adjacent to the positioning holes 131-137 of the printed circuit board 100 when the printed circuit board 10 is assembled, such as described herein. The projections 240-246 may provide support to the printed circuit board 100 when the elastomeric pads 340-346 of the housing 300 are respectively pressed against the printed circuit board 100 possibly adjacent to, and possibly extending at least partially into, the positioning holes 131-137.

In an embodiment, the wall 230 of the base 200 includes a projection 247. In this embodiment, the wall 230 may include a branching portion 248 that extends between two portions of the inner surface 232 of the wall 230. The projection 247 may project from either side of the branching portion 248 of the wall 230 in a partially cylindrical or other shape. The projection 247 may be positioned to be disposed adjacent to the positioning hole 138 of the printed circuit board 100 and the elastomeric pad 347 of the housing 300 when the printed circuit board 10 is assembled, as described herein. The projection 247 may provide support to the printed circuit board 100 when the elastomeric pad 347 of the housing 300 is pressed against the printed circuit board 100 possibly adjacent to, and possibly extending at least partially into, the positioning hole 138.

In various embodiments, the base 200 includes one or more locator pins. For example, in one embodiment, the base 200 includes four locator pins 250-253. The locator pins 250-253 may extend from the top face 236 of the wall 230 of the base 200. The locator pins 250-253 may extend from the projections 240, 242, 244, and 246, respectively. The locator pins 250-253 may be positioned and sized such that they respectively extend at least partially into the positioning holes 131, 133, 135, and 137 of the printed circuit board 100 during assembly of the printed circuit board assembly 10. The locator pins 250-253 of the base 200 may contribute to locating the printed circuit board 100 in a desired position with respect to the base 200.

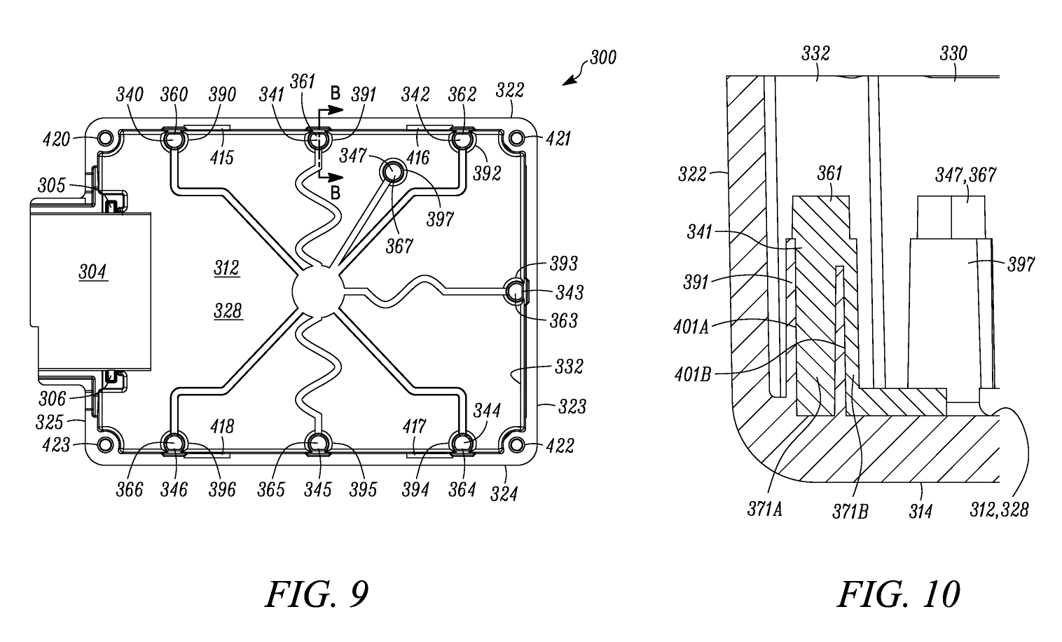

The base 200 may be snap-fitted or otherwise secured to the housing 300 over the printed circuit board 100 when assembling the printed circuit board assembly 10. For example, the base 200 may include snap locks 265-268, as shown in FIG. 3. The snap locks 265-268 may extend into snap recesses of the housing 300, such as, respectively, the snap recesses 415-418 shown in FIGS. 6 and 9.

The base 200 may include one or more screw holes, such as four base screw holes 260-263. After the base 200 and housing 300 have been snap-fitted together, screws (not shown) may respectively be inserted through the base screw holes 260-263 of the base 200 and into the housing screw holes 420-423 of the housing 300 described below. Inserting the screws may affix the base 200 and housing 300 together (and around the printed circuit board 100) during assembly of the printed circuit board assembly 10. Although screws may be used here to affix the base 200 and housing 300 and may therefore extend through the base 200 and housing 300, the screws do not extend through the printed circuit board 100. The screws may thus not transmit shock or vibration forces directly to the printed circuit board 100.

FIGS. 6-8 illustrate a top, front, and side view of a housing 300, respectively, for a printed circuit board assembly 10, in accordance with one embodiment. FIGS. 6-8 do not show elastomeric pads, which are described herein, and which may be included with the housing 300. Referring to FIGS. 6-8 along with FIGS. 1-2, the housing 300 may include an inner face 312 and outer face 314, and first side 322, second side 323, third side 324, and fourth side 325. The housing 300 may be made of a desired material or materials. For example, the housing 300 may be a radome in one or more of the embodiments described herein. The radome may include injection-molded RF-transparent plastic, or may include another material or materials.

The housing 300 may include a connector cover 304. The connector cover 304 may extend from the inner face 312 and fourth side 325 of the housing 300. The connector cover 304 may be shaped and sized to be positioned adjacent to the connector 104 of the printed circuit board 100 when the printed circuit board assembly 10 is assembled. The connector cover 304 may include connector slots 305-306. The connector slots 305-306 may respectively receive the connector ears 105-106 of the connector 104 to facilitate positioning the connector 104 adjacent to the connector cover 304. The connector cover 304, along with the connector seat 204 described above, may surround the connector 104, as shown in FIG. 11 described below, for example, when the printed circuit board assembly 10 is assembled.

As illustrated in the embodiment of FIG. 9, the housing 300, shown in the top view, may include an overmold 328. The overmold 328 may form the inner face 312 of the housing 300. The overmold 328 may form an outer layer of the pad supports 390-397, described below, if desired. If the overmold 328 is included with the housing 300, the connector cover 304 may extend from, or from just below, the inner face 312 of the housing 300. The overmold 328 may be a different material than that or those of other parts of the housing 300 if desired.

Referring to FIGS. 6-9 along with FIGS. 1-2, the housing 300 may include a wall 330, which may extend from the perimeter of the inner face 312 of the housing 300. The wall 330 may surround the inner face 312 and form the first through fourth sides 322-325 of the housing 300. The wall 330 may be perpendicular or close to perpendicular to the inner face 312, or may have another relative orientation. The wall 330 may include an inner surface 332, which may face toward the interior of the printed circuit board assembly 10 as assembled. The wall 330 may be dimensioned such that the periphery of the printed circuit board 100 is positioned within the confines of the wall 330, adjacent to the inner surface 332, when the printed circuit board assembly 10 is assembled, such as shown in FIG. 11 described below.

In various embodiments, the housing 300 includes one or more elastomeric pads that are each positioned adjacent to a pad support. In one such embodiment, the housing 300 includes eight elastomeric pads 340-347 respectively positioned adjacent to eight pad supports 390-397.

The elastomeric pads 340-347 may each include a desired elastomer. In an embodiment, the elastomeric pads 340-347 respectively include heads 360-367. Each of the heads 360-367 may be at least partially cylindrical or another shape.

In an embodiment, the elastomeric pads 340-347 may also each include a first leg. For example, FIG. 10, which illustrates a cross section of the housing of FIG. 9 taken along the line B-B, shows the elastomeric pad 341 in more detail. The elastomeric pad 341 may include a first leg 371A, which may be an elongated member that extends from the head 361. The elastomeric pads 340 and 342-347 may include similar first legs 370A and 372A-377A, respectively, such as shown in the embodiments of FIGS. 11-12.

In an embodiment, each of the elastomeric pads 340-347 includes a second leg. For example, as shown in FIG. 10, the elastomeric pad 341 may include a second leg 371B in addition to the first leg 371A. The second leg 371B may extend from the head 361 of the elastomeric pad 341. The second legs of each of the elastomeric pads 340 and 342-347 are not shown, but may similarly extend from their heads 360 and 362-367, respectively.

Referring again to FIG. 6, the pad supports 390-397 may extend from the inner face 312 of the housing 300. If the inner face 312 is formed by the overmold 328, the pad supports 390-397 may extend from, or be at least partially formed by, the overmold 328.

The seven pad supports 390-396, and thus the elastomeric pads 340-346 respectively extending therefrom, may each be positioned adjacent to, and thus at least nearly in contact with, the inner surface 332 of the wall 330 of the housing 300. The pad support 397 may extend from the inner face 312 of the housing 300 at a nonadjacent position, away from the inner surface 332. Thus, the elastomeric pad 347 extending from the pad support 397 may also be nonadjacent.

Respectively, the pad supports 390-397 may be configured to receive the elastomeric pads 340-347 such that the heads 360-367 of the elastomeric pads 340-347 extend from the pad supports 390-397. In an embodiment, the heads 360-367 extend from the pad supports 390-397 such that the heads 360-367 are disposed at the ends of the pad supports 390-397, as is shown, for example, in FIGS. 1-2 and 9.

In an embodiment such as shown in FIG. 6, the pad supports 390-397 include apertures 400A-407A, respectively. The apertures 400A-407A may be shaped and sized such that the first legs 370A-377A of the elastomeric pads 340-347 respectively extend into the apertures 400A-407A. For example, FIG. 10 shows the first leg 371A of the elastomeric pad 341 extending into the aperture 401A. The apertures 400A-407A of the pad supports 390-397 may be shaped and sized as slightly smaller cylinders than those of the first legs 370A-377A of the elastomeric pads 340-347. In this example, the apertures 400A-407A may secure the first legs of the elastomeric pads 340-347 therein, respectively, by interference fit. The apertures 400A-407A and first legs 370A-377A may be otherwise shaped and sized such that the apertures 400A-407A secure the first legs 370A-377A therein.

In an embodiment, the pad supports 390-397 include grooves 400B-407B, respectively. The grooves 400B-407B may be respectively shaped and sized to receive the second legs of the elastomeric pads 340-347, such as shown in FIG. 10 with respect to the groove 401B of the pad support 391 and the second leg 371B of the elastomeric pad 341. The grooves 400B-407B may be elongated grooves, and the second legs of the elastomeric pads 340-347 may be elongated members shaped and sized to at least partially fit within the respective grooves 400B-407B. The grooves 400B-407B of the pad supports 390-397 and second legs of the elastomeric pads 340-347 may be otherwise shaped and sized and fitted. The second legs of the elastomeric pads 340-347 may contribute to positioning and/or securing the elastomeric pads 340-347 with respect to the grooves 400B-407B and pad supports 390-397.

The pad supports 390-397 may be positioned to be disposed in alignment with the holes 131-138 of the printed circuit board 100 when the printed circuit board 10 is assembled. Thus, when the printed circuit board assembly 10 is assembled, such as described below, the heads 360-367 of the elastomeric pads 340-347 of the housing 300 may respectively press against the printed circuit board 100 adjacent to, and possibly extending at least partially into, the holes 131-138 of the printed circuit board 100.

That pressing of the elastomeric pads 340-347 may provide both a lateral frictional force and normal force to the printed circuit board 100 to oppose relative movement of the printed circuit board 100. As compared to using screws that extend through the printed circuit board 100 and secure it against the base 200, applying pressure with the elastomeric pads 340-347 to secure the printed circuit board 100 against the base 200 may dampen shock and vibration in the printed circuit board 100 and the components contained on it. Thus, the elastomeric pads 340-347 may transmit less shock and vibration forces to the printed circuit board 100 than do screws that extend through the printed circuit board 100.

Though screws may be used to secure the base 200 and housing 300 together in the printed circuit board assembly 10, as described herein, those screws do not extend through the printed circuit board 100. Those screws may thus not directly transmit shock and vibration forces to the printed circuit board 100.

Additionally, using elastomeric pads 340-347 and fixed locator pins 250-253 to secure the printed circuit board 100 to the base 200 may provide locating constraints for the printed circuit board 100 and may be less expensive than using screws and creating screw holes. Assembly may also be faster by eliminating the hand labor to install the screws. Further, the tolerances with elastomeric pads and locator pins may be greater than with screws and their threaded holes.

As referenced above with respect to the base 200, the housing 300 may include snap recesses 415-418. The snap recesses 415-418, such as shown in FIGS. 6 and 9, may respectively receive the snap locks 265-268 of the base 200 to secure the base 200 and housing 300 together.

Also as referenced above with respect to the base 200, the housing 300 may include housing screw holes 420-423. Screws (not shown) may respectively be inserted through the base screw holes 260-263 of the base 200 and into the housing screw holes 420-423 to affix the base 200 and housing 300 together and around the printed circuit board 100.

FIG. 11 illustrates a perspective view of a printed circuit board assembly 10 as assembled, showing some internal components, in accordance with one embodiment. As shown, the printed circuit board 100 is disposed adjacent to both the base 200 and housing 300. The printed circuit board assembly 10 may be placed into that configuration as follows, though the order and way of assembly may differ in other embodiments.

The printed circuit board 100 may be positioned onto the top face 236 of the wall 230 of the base 200 such that the locator pins 250-253 extending from the top face 236 respectively extend at least partially into the positioning holes 131, 133, 135, and 137 of the printed circuit board 100. For example, FIG. 12, which illustrates a cross section of the printed circuit board assembly 10 of FIG. 11 taken along line C-C, shows the locator pins 250 and 251 respectively extending into the positioning holes 131 and 133.

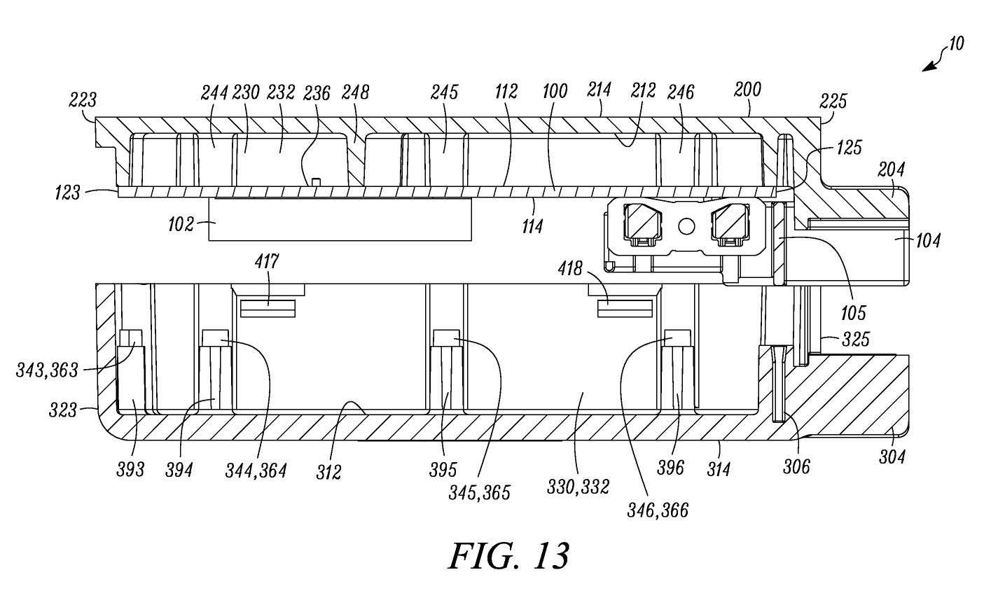

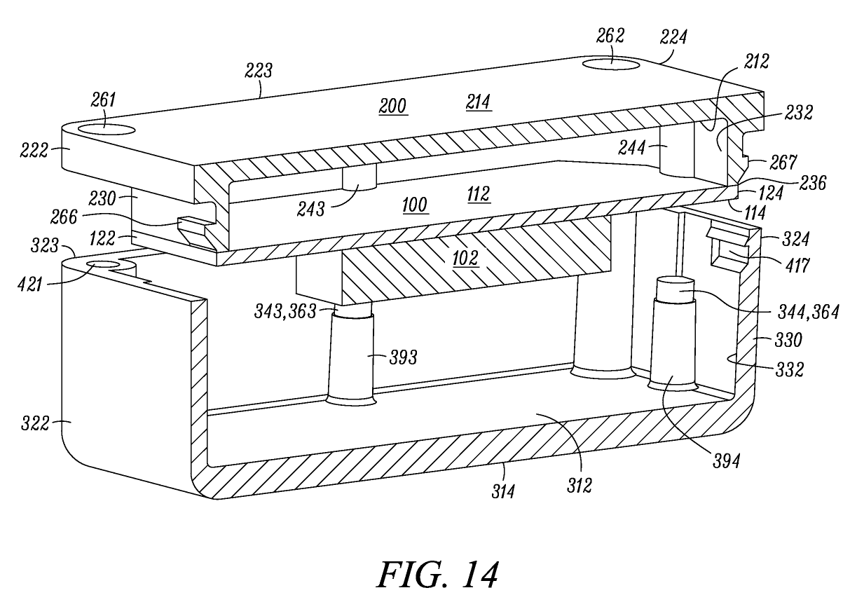

FIGS. 13-14 illustrate cross sections of the components of the printed circuit board assembly of FIG. 11 taken along lines D-D and E-E, respectively, with the printed circuit board 100 and base 200 positioned together. As positioned together, the periphery of the first face 112 of the printed circuit board 100 is disposed adjacent to the top face 236 of the wall 230 of the base 200.

The projections 240-247 of the base 200 may also be disposed in alignment with, and thus adjacent to, the positioning holes 131-138 of the printed circuit board 100. The positioning holes 131-138 and projections 240-247 are respectively shown in, e.g. FIGS. 1 and 3.

Also, as shown in FIG. 13, for example, the connector 104 of the printed circuit board 100 may be disposed adjacent to the connector seat 204 of the base 200 when assembled.

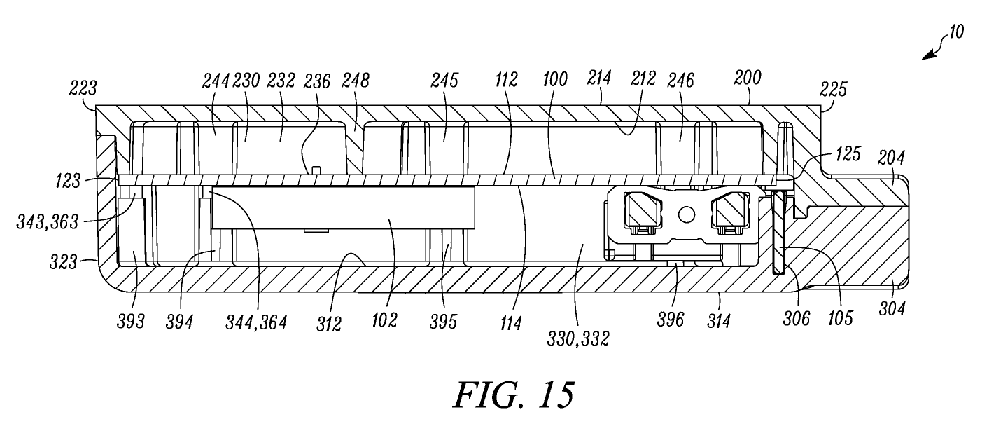

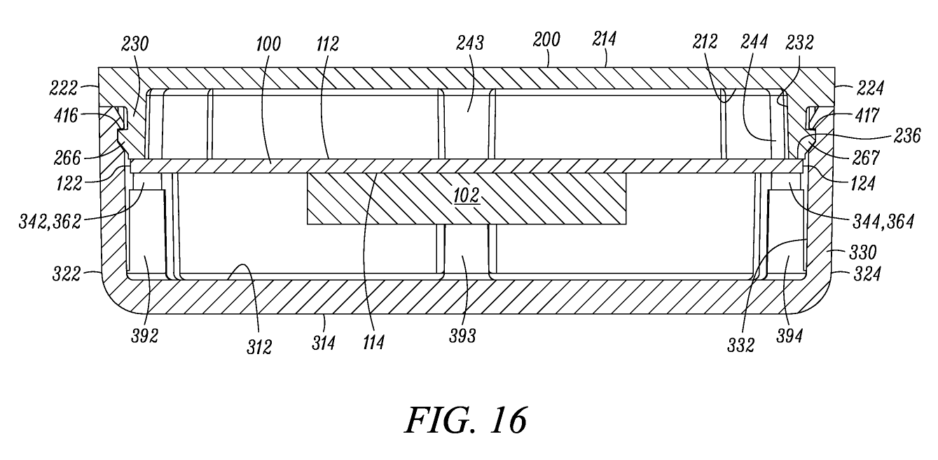

The housing 300 may be snap-fitted to the base 200, over the printed circuit board 100, such as described above with respect to the snap recesses 415-418 of the housing 300 and snap locks 265-268 of the base 200. For example, the embodiments of FIGS. 15-16 illustrate the cross section and a front view of FIGS. 13-14, respectively, but with the housing 300 snap-fitted to the base 200 and around the printed circuit board 100. As shown in the embodiment of FIG. 16, the snap recesses 416-417 of the housing 300 are respectively positioned around the snap locks 266-267 of the base 200.

When the housing 300 is snap-fitted to the base 200 and around the printed circuit board 100, the elastomeric pads 340-347 of the housing 300 may be aligned such that they contact the printed circuit board 100 adjacent to the positioning holes 131-138. The elastomeric pads 340-347 of the housing 300 may thus press against the printed circuit board 100 adjacent to, and possibly extending at least partially into, the positioning holes 131-138. FIGS. 11 and 15-16 each show some of the elastomeric pads 340-347 pressed against the printed circuit board 100.

The connector cover 304 of the housing 300 may be positioned adjacent to the connector 104 of the printed circuit board 100. The connector seat 204 of the base 200 and the connector cover 304 may surround the connector 104 as assembled, such as referred to above and shown in FIG. 11, for example.

As described above, the base 200 and housing 300 may be further secured together and around the printed circuit board 100 by inserting screws (not shown) through the base screw holes 260-263 of the base 200 and into the housing screw holes 420-423 of the housing 300. In this embodiment, the screws do not extend through the printed circuit board 100.

In embodiments of the printed circuit board assembly 10, the printed circuit board 100 may have less or more than the eight positioning holes 131-138. In various embodiments, the base 200 may have more or less than the eight projections 240-247 and four locator pins 250-253. Each of the one or more locator pins may extend from one of the one or more projections, e.g., the base may include four projections with a locator pin extending from each projection. In various embodiments, the housing 300 may have more or less than the eight elastomeric pads 340-347 and eight pad supports 390-397, and each elastomeric pad may extend from a pad support. The number and location of the positioning holes of the printed circuit board 100, the projections and pins of the base 200, and the elastomeric pads of the housing 300 may correspond so as to be aligned during assembly of the printed circuit board assembly 10. For example, the printed circuit board 100 may include one or more positioning holes located such that in an assembled printed circuit board assembly 10, each of the one or more locator pins of the base 200 extends into one of the positioning holes. Each of the one or more elastomeric pads of the housing 300 may contact the printed circuit board 100 adjacent to, and possibly extending at least partially into, one of the one or more positioning holes. As another example of an embodiment, the housing 300 may include one or more pad supports, each of which may extend from the inner face 312 of the housing 300. The head of each of the one or more elastomeric pads may extend from one of the pad supports. Each of the pad supports may include an aperture, and each of the elastomeric pads may include a first leg that is to extend into the aperture of one of the pad supports. Thus, for each elastomeric pad, the first leg may extend into the aperture of the pad support from which its head extends, such as shown in FIG. 10 with respect to the head 361 and first leg 371A of the elastomeric pad 341 and aperture 401A of the pad support 391. Each pad support may also include a groove, and each elastomeric pad may also include a second leg. The first leg and the second leg of each elastomeric pad may respectively extend into the aperture and the groove of one of the pad supports. Thus, for each elastomeric pad, the second leg may extend into the groove of the pad support from which its head extends, such as shown in FIG. 10 with respect to the head 361 and second leg 371B of the elastomeric pad 341 and groove 401B of the pad support 391.

In other embodiments, the elastomeric pads 340-347 of the housing 300 may each not include one or both their first and second legs. In these embodiments, the elastomeric pads 340-347 may be secured to their respective pad supports or another part of the housing 300 as desired, such as by adhesive or interference fit or other means.

In another embodiment, one or more of the pad supports, e.g. 390-397, of the housing 300 may not be positioned to be disposed in alignment with positioning holes of the printed circuit board 100 when the printed circuit board 10 is assembled. Thus, when the printed circuit board assembly 10 is assembled, the heads 360-367 of the elastomeric pads 340-347 of the housing 300 may contact the printed circuit board 100. However, in this embodiment, one or more of the heads 360-367 may not be adjacent to, or extend at least partially into, a positioning hole of the printed circuit board 100.

In other embodiments, the locator pins 250-253 may not respectively extend from projections 240, 242, 244, and 246 of, or otherwise from, the top face 236 of the wall 230, but may extend from other portions of the base 200.

In other embodiments, the housing 300 may be secured to the base 200 and around the printed circuit board 100 by means other than one or both of snap-fitting and screwing.

Numerous specific details have been set forth herein to provide a thorough understanding of the embodiments. It will be understood by those skilled in the art, however, that the embodiments may be practiced without these specific details. In other instances, well-known operations, components and circuits have not been described in detail so as not to obscure the embodiments. It can be appreciated that the specific structural and functional details disclosed herein may be representative and do not necessarily limit the scope of the embodiments.

It is also worthy to note that any reference to “one embodiment” or “an embodiment” means that a particular feature, structure, or characteristic described in connection with the embodiment is included in at least one embodiment. The appearances of the phrase “in one embodiment” in various places in the specification are not necessarily all referring to the same embodiment.

While certain features of the embodiments have been illustrated as described herein, many modifications, substitutions, changes and equivalents will now occur to those skilled in the art. It is therefore to be understood that the appended claims are intended to cover all such modifications and changes as fall within the true spirit of the embodiments.

1. A printed circuit board assembly, comprising:
a printed circuit board;
a housing including one or more elastomeric pads and one or more snap lock recesses, wherein each of the one or more elastomeric pads are affixed to said housing and press against the underside of said printed circuit board; and
a base secured to said housing via (a) snap locks on said base configured to extend into said snap recesses on said housing, (b) screws that do not penetrate said printed circuit board, or (c) both said snap locks and said screws, wherein said base and said housing enclose said printed circuit board.

2. The printed circuit board assembly of claim 1, the printed circuit board including one or more positioning holes, each of the one or more elastomeric pads to contact the printed circuit board adjacent to one of the one or more positioning holes.

3. The printed circuit board assembly of claim 1, the printed circuit board including one or more positioning holes, each of the one or more elastomeric pads to extend at least partially into one of the one or more positioning holes.

4. The printed circuit board assembly of claim 1, the housing further including one or more pad supports to which said elastomeric pads are affixed, each of the one or more elastomeric pads including a head that is to extend from one of the one or more pad supports.

5. The printed circuit board assembly of claim 1, the housing further including one or more pad supports each including an aperture, each of the one or more elastomeric pads including a first leg that is to extend into the aperture of one of the one or more pad supports.

6. The printed circuit board assembly of claim 1, the housing further including one or more pad supports each of said one or more pad supports including an aperture and a groove, each of the one or more elastomeric pads including a first leg and a second leg, the first leg and the second leg of each of the one or more elastomeric pads to respectively extend into the aperture and the groove of each one of the one or more pad supports.

7. The printed circuit board assembly of claim 1, the one or more elastomeric pads including eight elastomeric pads.

8. The printed circuit board assembly of claim 7, the printed circuit board including eight positioning holes, each of the eight elastomeric pads (i) to contact the printed circuit board adjacent to one of the eight positioning holes, or (ii) to extend at least partially into one of the eight positioning holes.

9. (canceled)

10. The printed circuit board assembly of claim 7, the housing further including a wall, the wall including an inner surface, seven of the eight elastomeric pads positioned adjacent to the inner surface.

11. The printed circuit board assembly of claim 7, the housing further including eight pad supports, each of the eight elastomeric pads including a head that is to extend from one of the eight pad supports.

12. The printed circuit board assembly of claim 1, wherein the housing includes a radome.

13. The printed circuit board assembly of claim 1, wherein said base further comprises one or more locator pins, the printed circuit board including one or more positioning holes, each of the one or more locator pins to extend into one of the one or more positioning holes.

14. The printed circuit board assembly of claim 13, the base further including a wall, the wall including one or more projections, each of the one or more locator pins extending from one of the one or more projections.

15. The printed circuit board assembly of claim 14, the one or more projections including at least four projections, the one or more locator pins including at least four locator pins.

16. A housing for a printed circuit board assembly, comprising:
an inner face;
one or more pad supports, each of the one or more pad supports extending from the inner face;
one or more elastomeric pads, each of the one or more elastomeric pads including a head that is to extend from one of the one or more pad supports, wherein said one or more elastomeric pads are affixed to said pad supports and press against the underside of said printed circuit board; and
one or more snap lock recesses.

17. The housing of claim 16, the one or more pad supports each further including an aperture, each of the one or more elastomeric pads further including a first leg that is to extend into the aperture of the pad support from which its head is to extend.

18. The printed circuit board assembly of claim 17, each of the one or more pad supports further including a groove, each of the one or more elastomeric pads further including a second leg that is to extend into the groove of the pad support from which its head is to extend.

19. The housing of claim 16, the one or more pad supports including eight pad supports, and the one or more elastomeric pads including eight elastomeric pads.

20. The housing of claim 19, further including a wall, the wall including an inner surface, seven of the eight pad supports positioned adjacent to the inner surface.

21. The housing of claim 16, wherein the housing includes (i) a radome, or (ii) a radome and a connector cover.

22. (canceled)

23. The printed circuit board assembly of claim 1, wherein a connector is connected to said printed circuit board and said connector extends outward from a side of said housing.

24. The printed circuit board assembly of claim 4, wherein said elastomeric pad supports extend out from said housing to accommodate a connector attached to said printed circuit board.
